(19) United States
(12) Patent Application Publication
(10) Pub. No.: US 2026/0177625 A1
(43) Pub. Date: Jun. 25, 2026

(54) DEVICE FOR ESTIMATING BATTERY STATE OF CHARGE USING COULOMB COUNTER

(71) Applicants: Silicon Mitus, Inc., Seongnam-si (KR); SILICON-MAGIC SEMICONDUCTOR TECHNOLOGY (HANGZHOU) CO., LTD., Hangzhou City (CN)

(72) Inventors: Sang Woo Lee, Seongnam-si (KR); Dae Sun Kim, Gwangcheon-si (KR); Jong Yeon Na, Seoul (KR)

(73) Assignees: Silicon Mitus, Inc., Seongnam-si (KR); SILICON-MAGIC SEMICONDUCTOR TECHNOLOGY (HANGZHOU) CO., LTD., Hangzhou City (CN)

(21) Appl. No.: 19/346,171

(22) Filed: Sep. 30, 2025

(30) Foreign Application Priority Data
Dec. 23, 2024 (KR) 10-2024-0194631

(51) Int. Cl. G01R 31/367; G01R 31/3842; G01R 31/389

(52) U.S. Cl. CPC G01R 31/367; G01R 31/3842; G01R 31/389

(57) ABSTRACT

A device for estimating a battery's state of charge includes: a first coulomb counter that calculates a first charge variation amount Δ Q in each period by integrating the battery current Im for every predetermined period; a second coulomb counter that calculates a first estimated charge amount Qm by integrating the first charge variation amount Δ Q; a compensator that calculates a second charge variation amount Δ Q_comp by compensating for the first charge variation Δ Q using the first estimated charge amount Qm and the second estimated charge amount Qe; a third coulomb counter that calculates a second estimated charge amount Qe by integrating the second charge variation amount Δ Q_comp; and an estimator that estimates a battery's state of charge based on the second estimated charge amount Qe.

### CROSS-REFERENCE TO RELATED APPLICATIONS

This application claims the benefit of Korea Patent Application No. 10-2024-0194631, filed on Dec. 23, 2024, which is incorporated herein by reference for all purposes as if fully set forth herein.

### BACKGROUND

The present disclosure relates to a device for estimating a battery's state of charge using a coulomb counter. More specifically, the present disclosure can reduce the estimation errors of a state of charge due to the accumulation of errors of the current detection in estimating a battery's state of charge using a coulomb counter. In addition, it can improve the accuracy of estimating a battery's state of charge by compensating for the battery temperature and aging characteristics.

A technique based on a coulomb counter is widely used for estimating a battery's state of charge. The method for estimating a battery's state of charge using a coulomb counter detects the battery current and integrates the battery current to estimate the amount of charge, and estimate the battery's state of charge based on the estimated state of charge of the battery. The method for estimating a battery's state of charge using a coulomb counter, also known as coulomb counting, is widely used for its advantage of being able to estimate the state of charge relatively accurately using a simple method.

However, a general method for estimating a battery's state of charge using a coulomb counter estimates the amount of a battery's residual charge continuously by cumulatively adding the measured current. Therefore, even a slight error in the measured current can result in a significant error in predicting the amount of a battery's residual charge as such errors accumulate over time.

In addition, there is still room in the field of improving a general method of estimating a battery's state of charge using a coulomb counter in that it does not reflect the change in the battery characteristics associated with the battery temperature and aging. For example, when a battery is placed in cold temperatures or aging, a full charge capacity (or available capacity) of a battery can be considerably reduced compared to the design capacity. If such decrease in full charge capacity is not reflected, the ability to accurately estimate a state of charge can be reduced.

### PRIOR ART DOCUMENT

### Patent Document

(Patent Document 1) Korean Patent Application Publication No. 10-2021-0137763 (published on Nov. 18, 2021)
(Patent Document 2) Japanese Laid-Open Patent Application Publication No. 2015-224975 (published on Dec. 14, 2015)
(Patent Document 3) Japanese Laid-Open Patent Application Publication No. 2009-109269 (published on May 21, 2009)

### SUMMARY

The present disclosure, according to one or more embodiments, seeks to resolve a problem in which the accuracy of estimating a state of charge is reduced due to the accumulation of errors in current measurement or the like when estimating a battery's state of charge using a coulomb counter.

The present disclosure, according to one or more embodiments, seeks to improve the accuracy of estimating a state of charge by reflecting changes in the battery characteristics associated with the battery temperature and aging when estimating a battery's state of charge using a coulomb counter.

The present disclosure, according to one or more embodiments, seeks to estimate a battery's state of charge based on the full charge capacity changed according to the battery temperature and aging when estimating a battery's state of charge using a coulomb counter.

The present disclosure, according to one or more embodiments, seeks to simplify the structure in estimating a battery's state of charge using a coulomb counter, and reduce the power consumption used for estimating a state of charge.

The device for estimating a battery's state of charge according to the present disclosure to solve the technical problems comprises; a first coulomb counter that calculates a first charge variation amount Δ Q in each period by integrating the battery current Im for every predetermined period; a second coulomb counter that calculates a first estimated charge amount Qm by integrating the first charge variation amount Δ Q; a compensator that calculates a second charge variation amount Δ Q_comp by compensating for the first charge variation Δ Q using the first estimated charge amount Qm and the second estimated charge amount Qe; a third coulomb counter that calculates a second estimated charge amount Qe by integrating the second charge variation amount Δ Q_comp; and an estimator that estimates a battery's state of charge based on the second estimated charge amount Qe.

In the device for estimating a battery's state of charge according to the present disclosure, the compensator uses the second estimated charge amount Qe to calculate an estimated open circuit voltage OCVe, and uses the estimated open circuit voltage OCVe to calculate the second charge variation amount Δ Q_comp.

In the device for estimating a battery's state of charge according to the present disclosure, the compensator uses a first lookup table LUT1 that contains data about the relationship between the amount of charge Q and the open circuit voltage OCV of a battery when calculating the estimated open circuit voltage OCVe by using the second estimated charge amount Qe.

In the device for estimating a battery's state of charge according to the present disclosure, the compensator calculates the second charge variation amount Δ Q_comp by compensating for the first charge variation amount Δ Q so that the difference between the estimated open circuit voltage OCVe and battery voltage Vm is reduced when the magnitude of the battery current Im is smaller than a first threshold value.

In the device for estimating a battery's state of charge according to the present disclosure, the compensator calculates the second charge variation amount Δ Q_comp based on the value in which the estimated open circuit voltage OCVe is subtracted from the battery voltage Vm multiplied by a first constant C1.

In the device for estimating a battery's state of charge according to the present disclosure, the first constant C1 is predetermined based on the internal resistance of the battery.

In the device for estimating a battery's state of charge according to the present disclosure, the compensator calculates a compensation coefficient the charge variation amount COMP_RATE of based on the ratio of the predicted remaining discharge time by voltage RTV calculated according to the battery voltage Vm and the predicted remaining discharge time by coulomb RTQ calculated according to the second estimated charge amount Qe, and calculates the second charge variation amount Δ Q_comp by multiplying the first charge variation amount Δ Q by the compensation coefficient of the charge variation amount COMP_RATE.

In the device for estimating a battery's state of charge according to the present disclosure, the predicted remaining discharge time by coulomb RTQ is defined by the time it takes for a remaining capacity of a battery to reach zero in the battery's discharge condition.

In the device for estimating a battery's state of charge according to the present disclosure, the predicted remaining discharge time by coulomb RTQ is calculated based on the value in which the second estimated charge amount Qe is divided by the absolute value obtained by multiplying the battery current Im by the compensation coefficient of the charge variation amount COMP_RATE.

In the device for estimating a battery's state of charge according to the present disclosure, the predicted remaining discharge time by voltage RTV is the time it takes for the current battery voltage Vm to reach the termination voltage Vterm in the battery's discharge condition.

In the device for estimating a battery's state of charge according to the present disclosure, the predicted remaining discharge time by voltage RTV is calculated based on the value obtained by multiplying the value subtracting the battery voltage Vm from the termination voltage Vterm by the inverse of the open circuit voltage slope Δ T/Δ Q\OCVm.

In the device for estimating a battery's state of charge according to the present disclosure, the compensator creates the predicted remaining discharge time based on a first correction voltage RTV_1^{st} by linearizing discontinuous components of the predicted remaining discharge time by voltage RTV.

In the device for estimating a battery's state of charge according to the present disclosure, the compensator creates the predicted remaining discharge time based on a second correction voltage RTV_2^{nd} by compensating for the characteristic difference according to the discharge current and battery temperature of the predicted remaining discharge time based on the first correction voltage RTV_1^{st}.

The present disclosure, according to one or more embodiments, can improve the problem that the accuracy of the state of charge estimation is degraded due to the accumulation of errors such as current measurement in estimating a battery's state of charge using a coulomb counter.

The present disclosure, according to one or more embodiments, can improve the accuracy of the state of charge estimation by reflecting the change in terms of battery characteristics due to the temperature and aging of a battery in estimating a battery's state of charge using a coulomb counter.

The present disclosure, according to one or more embodiments, can estimate a battery's state of charge based on the full charge capacity changed according to the temperature and aging of a battery in estimating a battery's state of charge using a coulomb counter.

The present disclosure, according to one or more embodiments, can reduce power consumption used for estimating a state of charge and simplify the structure in estimating a battery's state of charge using a coulomb counter.

### BRIEF DESCRIPTION OF THE DRAWINGS

FIG. 1 is an illustration of a device for estimating a battery's state of charge according to one or more embodiments of the present disclosure.

FIG. 2 is an exemplary illustration of the overall configuration calculating the compensation coefficient of the charge variation amount COMP_RATE based on the ratio of the predicted remaining discharge time by coulomb RTQ and the predicted remaining discharge time by voltage RTV according to one or more embodiments of the present disclosure.

FIG. 3 is an exemplary illustration of a configuration calculating RTV by using the termination voltage Vterm, battery voltage Vm, open circuit voltage OCVm according to one or more embodiments of the present disclosure.

FIG. 4 is an exemplary illustration of the uncorrected RTV according to one or more embodiments of the present disclosure.

FIG. 5 conceptually illustrates a first correction that converts RTV into RTV_ref according to one or more embodiments of the present disclosure.

FIG. 6 is an exemplary flowchart of a first correction of RTV according to one or more embodiments of the present disclosure.

FIG. 7 illustrates an exemplary simulation result for a first correction of RTV performed under the discharge condition of −0.02 C at 25° C.

FIG. 8 is an exemplary illustration of a voltage characteristic in the discharge current condition of −0.8 A according to one or more embodiments of the present disclosure.

FIG. 9 is an exemplary illustration of a voltage characteristic by discharge current in the temperature condition of 25° C. according one or more embodiments of the present disclosure.

FIG. 10 is an exemplary illustration of the first correction result for a voltage profile in the condition of −0.8 A at 25° C. according to one or more embodiments of the present disclosure.

FIG. 11 is an exemplary illustration of the first correction result of a voltage profile in the condition of −0.8 A at 10° C. according to one or more embodiments of the present disclosure.

FIG. 12 is an exemplary flowchart of a second correction of RTV according to one or more embodiments of the present disclosure.

FIG. 13 illustrates an exemplary simulation result of a first correction and second correction of RTV performed in the discharge condition of −0.8 A at 25° C. according to one or more embodiments of the present disclosure.

FIG. 14 illustrates an exemplary simulation result of a first correction and a second correction of RTV performed in the discharge condition of −0.8 A at −10° C.

FIG. 15 is an exemplary flowchart to calculate the compensation coefficient of the charge variation amount COMP_RATE according to one or more embodiments of the present disclosure.

FIGS. 16-19 are diagrams illustrating the effects according to one or more embodiments of the present disclosure in comparison with the prior art.

It is to be understood that the specific structural or functional description of embodiments of the present invention disclosed herein is for illustrative purposes only and is not intended to limit the scope of the inventive concept but may be embodied in many different forms and not limited to the embodiments set forth herein.

The embodiments according to the concept of the present invention can make various changes and can take various forms, so that the embodiments are illustrated in the drawings and described in detail herein. It should be understood, however, that it is not intended to limit the embodiments according to the concepts of the present invention to the particular forms disclosed, but includes all modifications, equivalents, or alternatives falling within the spirit and scope of the invention.

Unless defined otherwise, all terms including technical and/or scientific terms used herein have the same meaning as commonly understood by one of ordinary skill in the art to which this invention belongs. These terms, such as commonly used predefined terms, have the same meaning as in the related art and should not be construed as ideal or ambiguous unless explicitly defined in this specification.

Hereinafter, after describing the basic principles of the present disclosure first, the embodiments of the present disclosure will be described in detail.

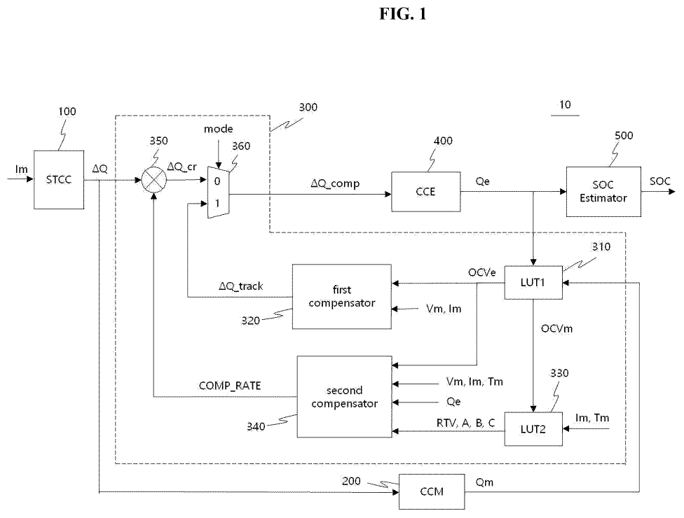

FIG. 1 illustrates the device for estimating a battery's state of charge according to one or more embodiments of the present disclosure.

Referring to FIG. 1, the device for estimating a battery's state of charge 10 can include a first coulomb counter 100 STCC; a second coulomb counter 200 CCM; a third coulomb counter 400 CCE; and a state of charge estimator 500 SOC Estimator.

The device for estimating a battery's state of charge 10 can be used to estimate a battery's state of charge in various devices that use batteries. For example, the device for estimating a battery's state of charge 10 can be effective in portable electronic devices such as smartphones, tablets, and laptops; however, its application is not limited to them. The device for estimating a battery's state of charge 10 may be implemented as a separate device in various types of devices or may be implemented in various ways such as one functional element inside of other devices that are originally installed in the device (e.g. controller).

The first coulomb counter 100 calculates the first charge variation amount Δ Q by integrating the battery current Im for each period.

Battery current Im may be a value that detects currents to charge or discharge the battery. A conventional current detection means can be used to detect the battery current Im. For example, a current detection resistor or current transformer, but is not limited to, can be used. A battery current Im detection means may be a component included in the device for estimating a battery's state of charge 10, however, a device for estimating a battery's state of charge 10 can obtain the battery current Im information from the external battery current Im detection means.

The first coulomb counter 100 performs an integration function for each period of the battery current Im. That is, the first coulomb counter 100 is reset after calculating the first charge variation amount Δ Q by integrating the battery current Im for every predetermined period, and then repeats the battery current Im integration for a predetermined period again. For example, the first coulomb counter 100 can calculate the first charge variation amount Δ Q by cumulatively summing a predetermined number of the digitalized sampling data of the battery current Im. In this case, the value obtained by multiplying the number of data integrated in the sampling period of the battery current Im can be understood as an integration period of the first coulomb counter 100.

The reason why the first coulomb counter 100 performs the integration by each period will be described below. As described in greater detail below, in the present embodiment, the second charge variation amount Δ Q_comp is calculated by compensating for the first charge variation amount Δ Q through the compensator 300 and then the second charge variation amount Δ Q_comp is integrated in the third coulomb counter 400 to calculate the second estimated charge amount Qe. When the first coulomb counter 100 is not used, the compensator 300 performs compensation operations for each of the sampled battery current Im. In this case, when each sampled battery current Im includes noise, the compensator 300 may not operate well, and it consumes high power as the operations of the compensator 300 are repeated. In the present embodiment, the first coulomb counter 100 is used to generate the first charge variation amount Δ Q for each period by integrating the battery current Im at every predetermined period, and the compensator 300 performs compensation operations on each period. In this case, since the first charge variation amount Δ Q is the value obtained from an integration of a plurality of sampling values of the battery current Im, which has the advantage of reducing not only noise effects but power consumption.

In this case, an integration period of the first coulomb counter 100 is preferably set to such an extent that changes in the battery state such as the battery current Im, the battery voltage Vm, and the state of charge SOC are not significant. When the integration period of the first coulomb counter 100 is set to be long enough that the change in the battery state is significant, it is not easy for the compensator 300 to perform an appropriate compensation function for the first charge variation amount Δ Q. For example, when the battery current Im is sampled through an analog-digital converter ADC approximately every 0.3 seconds and the first coulomb counter 100 is set to integrate the four to eight sampled battery current Im, it may be possible to ensure high accuracy of the state of charge estimation by appropriately compensating for the first charge variation amount Δ Q while reducing power consumption and noise effects.

The second coulomb counter 200, CCM integrates the first charge variation amount Δ Q to calculate the first estimated charge amount Qm. The second charge variation amount 200, unlike the third coulomb counter 400, can directly integrate the first charge variation amount Δ Q that is uncompensated.

The compensator 300 uses the first estimated charge amount Qm and the second estimated charge amount Qe to calculate the second charge variation amount Δ Q_comp by compensating the first charge variation amount Δ Q.

According to one or more embodiments, the compensator 300 uses the battery current Im, battery voltage Vm, and the second estimated charge amount Qe to calculate the second charge variation amount Δ Q_comp by compensating for the first charge variation amount Δ Q.

According to one or more embodiments, the compensator 300 uses the second estimated charge amount Qe to calculate the estimated open circuit voltage OCVe, and uses the estimated open circuit voltage OCVe to calculate the second charge variation amount Δ Q_comp by compensating for the first charge variation amount Δ Q.

According to one or more embodiments, the compensator 300 can calculate the compensation coefficient of the charge variation amount COMP_RATE based on the ratio of the predicted remaining discharge time by voltage RTV calculated according to the battery voltage Vm and the predicted remaining discharge time by coulomb RTQ calculated according to the second estimated charge amount Qe, and can calculate the second charge variation amount Δ Q_comp by multiplying the first charge variation amount Δ Q by the compensation coefficient of the charge variation amount COMP_RATE.

For example, the compensator 300 includes a first lookup table 310 LUT1, a first compensator 320, a second lookup table 330 LUT2, a second compensator 340, a multiplier 350, and multiplexer 360.

The first lookup table 310 LUT1 can include data on the relationship between the amount of charge Q and the open circuit voltage OCV of the battery. The compensator 300 uses the first lookup table 310 to calculate the estimated open circuit voltage OCVe based on the second estimated charge amount Qe. The estimated open circuit voltage OCVe calculated using the first lookup table 310 can be utilized in the first compensator 320 and the second compensator 340.

The first compensator 320 can operate to eliminate the accumulated errors of the second predicted charge amount Qe when the battery is in a relaxation state.

To this end, according to one or more embodiments, when the magnitude of the battery current Im is smaller than a first threshold value, the first compensator 320 can calculate the second charge variation amount Δ Q_comp by compensating for the first charge variation amount Δ Q in order to decrease the difference between the estimated open circuit voltage OCVe and the battery voltage Vm. According to one or more embodiments, the magnitude of the battery current Im may be, but is not limited to, the average of the absolute value of the battery current Im during an integration period of the first coulomb counter 100. In addition, according to one or more embodiments, the first compensator 320 can be set to operate only when it is determined that the magnitude of the battery current Im is smaller than the first threshold value persists for a predetermined number of times or more. The first threshold value can be a value sufficient to determine that a battery is in a somewhat relaxed state.

When a battery is determined to be in a relaxation state, the battery voltage Vm can be substantially equal to the actual open circuit voltage OCV of a battery. In this embodiment, it does not try to estimate the exact value of the actual open circuit voltage OCV of a battery as it does not use an equivalent model of a battery, or the like. The estimated open circuit voltage OCVe in the present embodiment is, as described below, a value that can be easily calculated by a lookup table or the like, from the second estimated charge amount Qe, and it is assumed that the estimated open circuit voltage OCVe differs from the actual open circuit voltage OCV to some extent. The present embodiment based on this assumption, assuming that the battery voltage Vm is more similar to the actual open circuit voltage OCV than the estimated open circuit voltage OCVe when the magnitude of the battery current Im is smaller than the first threshold, it is possible to eliminate the accumulated errors of the second estimated charge amount Qe by calculating the second charge variation amount Δ Q_comp so that the estimated open circuit voltage OCVe follows the battery voltage Vm by compensating for the first charge variation amount Δ Q.

When the state where the magnitude of the battery current Im is smaller than the first threshold value persists for a long period of time (for example for several hours) the battery will sufficiently be in a state of relaxation. Although the battery voltage Vm will be substantially equal to the actual open circuit voltage OCV when it is in the state, in the present embodiment, when the magnitude of the battery current Im is smaller than the first threshold value it is assumed that the battery voltage Vm is similar to the actual open circuit voltage OCV even if a sufficient time has not elapsed and the estimated open circuit voltage OCVe is operable to follow the battery voltage Vm.

According to the present embodiment, if the accumulated errors of the second estimated charge amount Qe increases during operation of a battery (even if the battery is not fully relaxed), it can be reduced. When the battery is fully relaxed, the errors of the second estimated charge amount Qe can almost be eliminated automatically by the same algorithm. That is, according to this embodiment, the accuracy of estimating a battery's state of charge can be improved by preventing the accumulation of errors in the second estimated charge amount Qe using a simple method without using complex systems for accurately estimating the actual open circuit voltage OCV by using a battery equivalent model, or the like.

According to one or more embodiments, as shown in equation 1 below, the second charge variation amount Δ Q_comp can be calculated based on the value multiplying the first constant C1 by the value obtained by subtracting the estimated open circuit voltage OCVe from the battery voltage Vm.

$$ΔQ\_comp = ( Vm - OCVe ) \cdot C 1 \qquad [ Equation 1 ]$$

In this case, the first constant C1 is a constant that affects the speed at which the estimated open circuit voltage OCVe follows the battery voltage Vm, which can be determined based on the internal resistance of the battery.

Equation 1 illustrates a case where the second charge variation amount Δ Q_comp is determined irrespective of the first charge variation amount Δ Q. However, alternatively, the second charge variation amount Δ Q_comp can be set so that the estimated open circuit voltage OCVe follows the battery voltage Vm while being subject to the first charge variation amount Δ Q.

In this way, the first compensator 320 can prevent the accumulation of errors in the second estimated charge amount Qe by allowing the estimated open circuit voltage OCVe to follow the battery voltage Vm when the magnitude of the battery current Im is smaller than the first threshold value (even if the battery is not fully relaxed).

The second lookup table 330 LUT2 can contain data for making the first correction and second correction to the predicted remaining discharge time by voltage RTV. The second compensator 340 uses the second lookup table 330 to linearize discontinuous components of the predicted remaining discharge time by voltage RTV to create the first corrected predicted remaining discharge time by voltage RTV_1^{st}, and can create the second corrected predicted remaining discharge time by voltage RTV_2^{nd} by correcting the characteristic differences depending on the discharge current and battery temperature of the first corrected predicted remaining discharge time by voltage RTV_1^{st}.

When the magnitude of the battery current Im is greater than the second threshold value, the second compensator 340 can calculate the compensation coefficient of the charge variation amount COMP_RATE based on the ratio of the predicted remaining discharge time by voltage RTV calculated according to the battery voltage Vm and the predicted remaining discharge time by coulomb calculated according to the second estimated charge amount Qe, and calculate the second charge variation amount Δ Q_comp by multiplying the compensation coefficient of the charge variation amount COMP_RATE by the first charge variation amount Δ Q.

For example, the magnitude of the battery current Im can be, but is not limited to, the average of an absolute value of the battery current Im during an integration period of the first coulomb counter 100. In addition, according to one or more embodiments, the second compensator 340 can be set to operate only when it is determined that the magnitude of the battery current Im is greater than the second threshold value persists for a predetermined number of times or more. The second threshold value can be set to a value sufficient to determine that a battery is in a charging or discharging operation state.

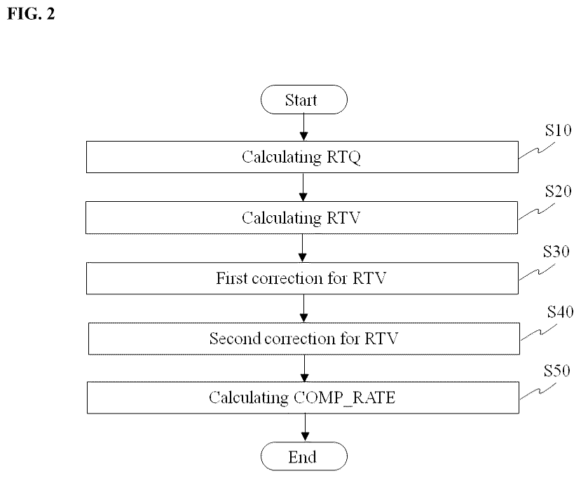

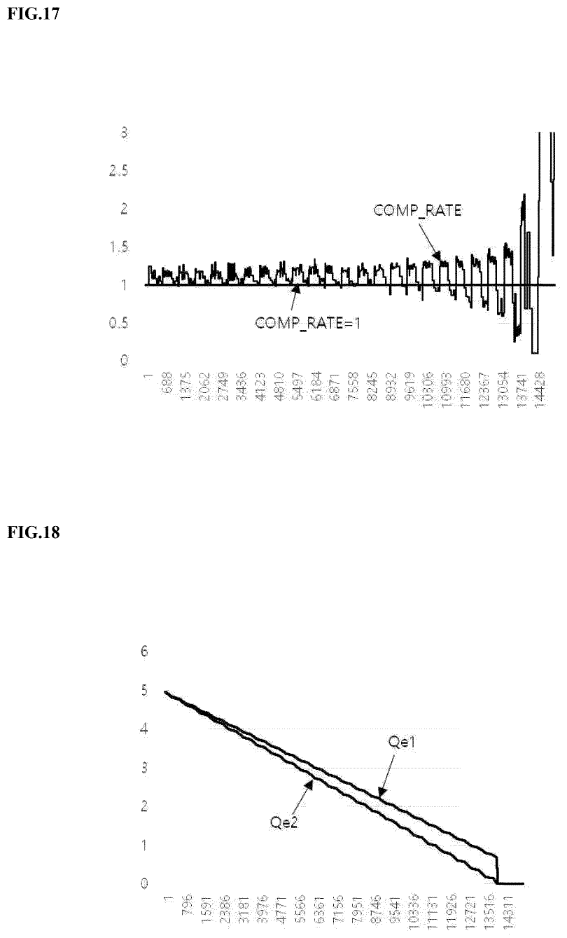

Hereinafter, with additional reference to FIGS. 2-19, the configuration of the second compensator 340 will be specifically, exemplarily described below.

According to one or more embodiments of the present disclosure, FIG. 2 is a drawing exemplarily illustrating an overall configuration for calculating the compensation coefficient of the charge variation amount COMP_RATE based on the ratio of the predicted remaining discharge time by coulomb RTQ and the predicted remaining discharge time by voltage RTV.

With further reference to FIG. 2, one or more embodiments of the present disclosure predicts the usable time of a battery at the time and predicts the reduction in charge amount Q of the battery by correcting the speed of the reduction in the battery's charge amount Q by the same. One or more embodiments of the present disclosure predicts two types of the battery usable time: First, the predicted remaining discharge time by voltage RTV that predicts the battery usable time based on the current battery voltage; and second, the predicted remaining discharge time by coulomb RTQ that predicts the usable time via the current second estimated charge amount Qe S20. When the usable time is predicted, the compensation coefficient of the charge variation amount COMP_RATE based on the ratio of RTV and RTQ to adjust the reduction speed of the current second estimated charge amount Qe. RTV has to be corrected twice as its value depends on the magnitude of the discharge current and temperature.

The predicted remaining discharge time by coulomb RTQ is the amount of time it takes for the current remaining capacity to reach 0 in a discharge condition of a battery, and can be calculated based on the value of the second estimated charge amount Qe divided by the absolute value of the product of the battery current Im and the compensation coefficient of the charge variation amount COMP_RATE.

That is, the predicted remaining discharge time by coulomb RTQ can be calculated using the following equation 2.

$$RTQ ( t ) = Qe ( t ) * 3600 / ( ABS ( Im ( t ) * COMP\_RATE ( t ) ) \qquad [ Equation 2 ]$$

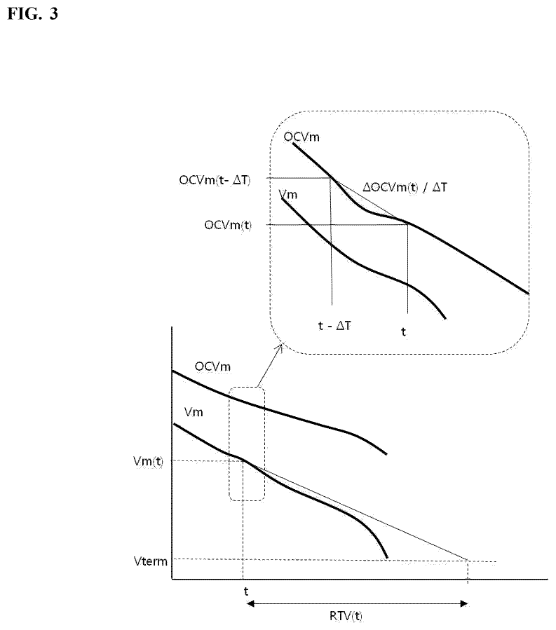

According to one or more embodiments of the present disclosure, FIG. 3 is a drawing for exemplarily illustrating a configuration for calculating RTV using the termination voltage of a battery Vterm, the battery voltage Vm, and the open circuit voltage OCVm.

With further reference to FIG. 3, RTV can be the amount of time it takes for the currently measured battery voltage Vm in the discharge condition of a battery to reach the termination voltage Vterm.

A battery's termination voltage Vterm varies depending on systems, but the battery's state of charge SOC should be 0% when it is terminated.

RTV at any point in time t can be calculated as the time until its value becomes the termination voltage Vterm by finding the straight line having an intercept Vm(t) and a slope of Δ OCVm/Δ T.

The equation of a straight line is shown in equation 3.

$$V = ( Δ OCVm / Δ T ) * t + Vm ( t ) \qquad [ Equation 3 ]$$

$$t = ( V - Vm ( t ) ) * Δ T / Δ OCVm ( t )$$

It is difficult for the battery voltage Vm to have a stable slope in the actual discharge condition due to quite a lot of noise. Therefore, the slope can be obtained with the open circuit voltage OCVm, which always monotonically decreases.

RTV at any point in time t can be calculated as the time until the battery voltage Vm becomes the termination voltage Vterm. Therefore, it can be calculated as shown in equation 4.

$$RTV ( t ) = ( Vterm - Vm ) ) * Δ T / Δ OCVm ( t ) \qquad [ Equation 4 ]$$

According to one or more embodiments, FIG. 4 is a drawing illustrating an uncorrected RTV.

With further reference to FIG. 4, since the waveform of RTV calculated by the equations 3 and 4 is not linear, it is difficult to predict the accurate RTV at any point in time. Therefore, RTV enables to calculate the remaining time more accurately through the first correction and second correction as described below.

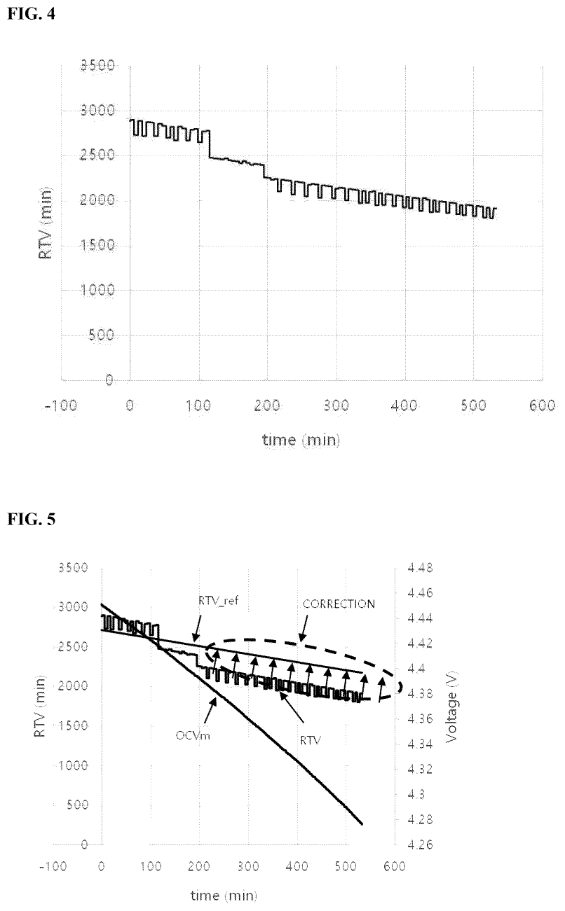

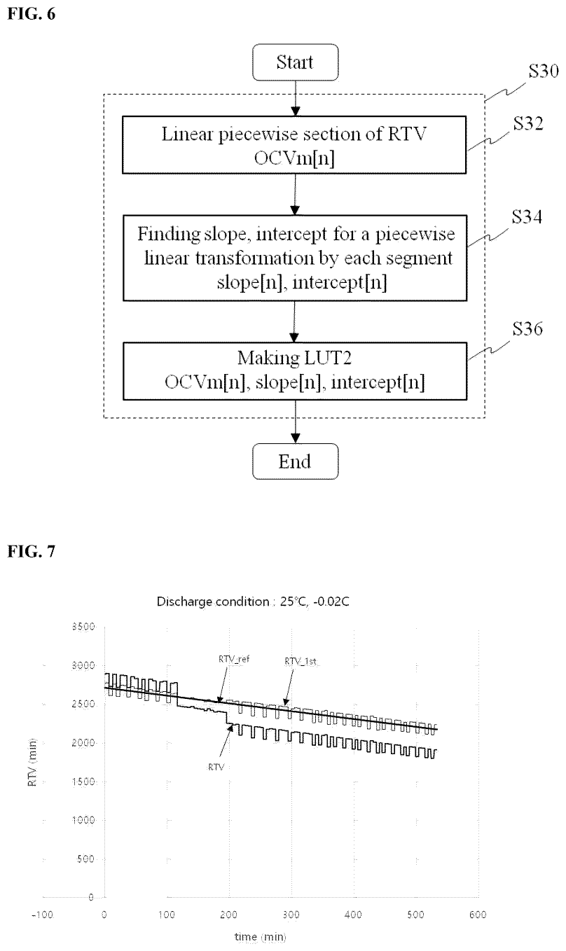

According to one or more embodiments of the present disclosure, FIG. 5 is a conceptual drawing illustrating the first correction for converting RTV into RTV_ref. According to one or more embodiments of the present disclosure, FIG. 6 is an exemplary illustration of the first corrected RTV.

Referring to FIG. 5 and FIG. 6, the first correction for RTV is to linearize the discontinuous RTV as illustrated in FIG. 5, and can create the second lookup table 330 through a processing order illustrated in FIG. 6. For example, the discharged vector can be used under the condition of 0.02C at 25° C.

RTV/RTV_ref is calculated for the first correction of RTV and the piecewise linear fitting can be performed on it. The piecewise linear fitting is a method of finding the best-fitting straight line in each segment by dividing data into several linear functions. In other words, instead of approximating the entire data with a single straight line, it is a method of representing the data more accurately by finding the best-fitting straight line in each segment, dividing the data into several segments according to their characteristics.

When the fitted linear equations are L[1], L[2], . . . , L[n], RTV_1^{st} which is the corrected LTV can be expressed in the equations 5 and 6 respectively.

$$L [ n ] = slope [ n ] * x + intercept [ n ] , OCVm [ n - 1 ] \leq x < OCVm [ n ] \qquad [ Equation 5 ]$$

$$RTV\_ 1 st = RTV * L [ n ] \qquad [ Equation 6 ]$$

As a more specific example, referring to FIG. 6, in step S32, a process of calculating OCVm[n] can be performed through a linear piecewise section of RTV; in step S34, a process of calculating a slope[n] and intercept[n] can be performed by finding a slope and intercept for a piecewise linear transformation for each segment; in step S36, a process of creating the second lookup table 330 that includes an OCVm[n], slope[n], and intercept[n] can be performed.

According to one or more embodiments of the present disclosure, FIG. 7 illustrates an exemplary simulation result for the first correction of RTV performed in the discharge condition of −0.02 C at 25° C.

Referring to FIG. 7, it can be seen that RTV_1^{st} which is the first corrected RTV accurately represents the remaining time like RTV_ref.

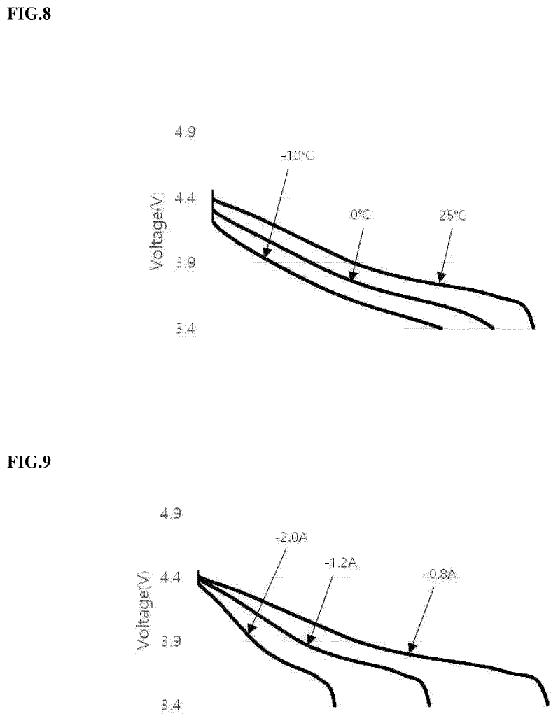

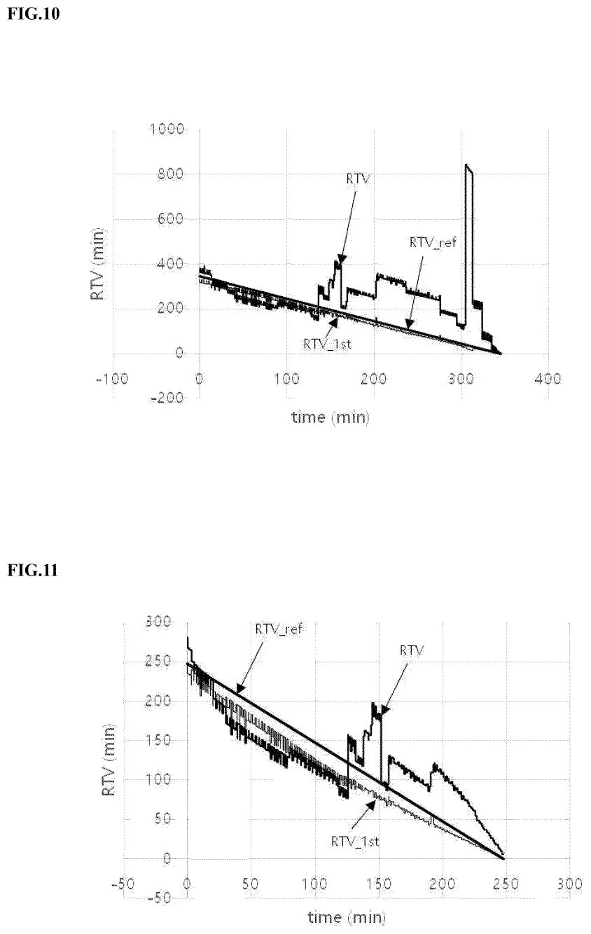

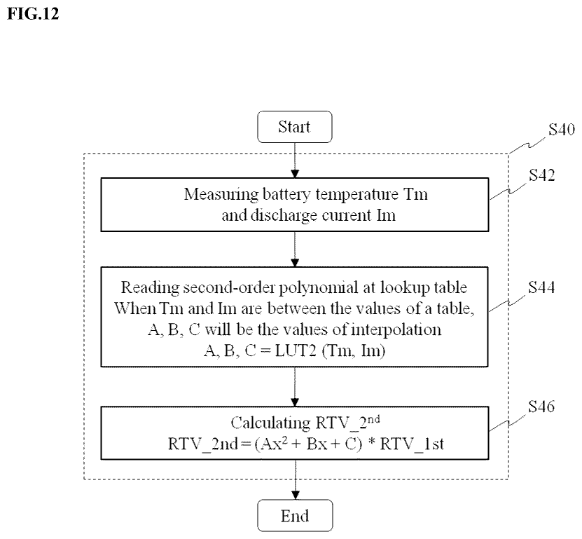

According to one or more embodiments of the present disclosure, FIG. 8 is an illustration of the voltage characteristics according to the temperature in the discharge current condition of −0.8 A; according to one or more embodiments of the present disclosure, FIG. 9 is an illustration of the voltage characteristics according to the discharge current in the temperature condition of 25° C.; according to one or more embodiments of the present disclosure, FIG. 10 is an illustration of the first correction results for the voltage profile in the condition of −0.8 A at 25° C.; and according to one or more embodiments of the present disclosure, FIG. 11 is an illustration of the first correction results for the voltage profile in the condition of −0.8 A at −10° C.

Referring to FIGS. 8-11, the simulation results of the first correction for RTV in various battery conditions are illustrated.

As illustrated in FIG. 8 and FIG. 9, the characteristics of the voltage profile depend on the discharge current and temperature of a battery.

FIG. 10 is an illustration of the simulation result of the first correction for RTV in the discharge condition of −0.8 A at 25° C. FIG. 11 is an illustration of the simulation result of the first correction for RTV in the discharge condition of −0.8 A at −10° C.

Referring to the examples shown in FIGS. 10 and 11, since the voltage profile characteristics for the voltage characteristics of the battery vary depending on the discharge current and temperature, there is an error in the first correction of the predicted remaining time by voltage RTV_1^{st} as a result of the first correction to RTV, and the second correction for RTV is applied to improve the error.

The second correction for RTV can be calculated by multiplying the first corrected predicted remaining time by voltage RTV_1^{st} as a result of the first correction for RTV by the second-order polynomial, which can be expressed by the following equation 7.

$$RTV\_ 2 nd = ( {Ax}^{2} + Bx + C ) * RTV\_ 1 st \qquad [ Equation 7 ]$$

$$x = OCVm\_MAX - OCVm$$

RTV_1^{st} is the first corrected predicted remaining time by voltage, RTV_2^{nd} is the second corrected predicted remaining time by voltage, and the coefficients of the second-order polynomial, A, B, and C, are the values saved on the second lookup table 330. OCVm_MAX is the maximum of OCVm, which is usually the battery's full charge voltage.

The coefficients of the second-order polynomial, A, B, and C, are different depending on the temperature and discharge current of the battery, and can be stored in the second lookup table 330.

Table 1 below shows an example of a battery's temperature and current conditions for obtaining coefficients of the second-order polynomial.

TABLE 1

| | Temper- | |
|---|---|---|
| NO | ature(° C.) | Current(A) |
| 1 | 40 | −2.0 |
| 2 | 40 | −1.2 |
| 3 | 40 | −0.8 |
| 4 | 25 | −2.0 |
| 5 | 25 | −1.2 |
| 6 | 25 | −0.8 |
| 7 | 0 | −2.0 |
| 8 | 0 | −1.2 |
| 9 | 0 | −0.8 |
| 10 | −10 | −2.0 |
| 11 | −10 | −1.2 |
| 12 | −10 | −0.8 |

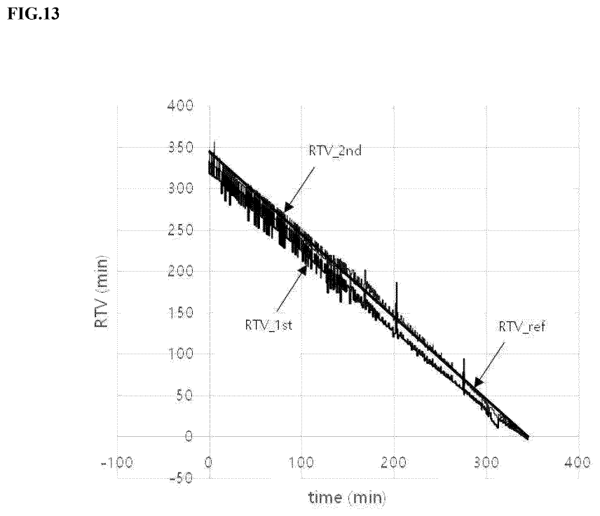

With further reference to FIG. 12, which is an exemplary flowchart of the second correction for RTV, a process of measuring the battery's temperature and discharge current can be performed in step S42.

In step S44, a process of reading the coefficients (A, B, and C) of the second-order polynomial from a second lookup table can be performed.

The coefficients (A, B, and C) of the second-order polynomial are matched to the discharge current Im and battery temperature Tm, and stored in the second lookup table 330, which can be expressed by the following equation.

$$A , B , C = LUT 2 ( Tm , Im ) \qquad [ Equation 8 ]$$

When the battery temperature Tm and discharge current Im fall between the values that are stored in the second lookup table 330, the interpolation of the values stored in the second lookup table 330 can be applied to the coefficients (A, B, and C) of the second-order polynomial.

In step S44, a process of calculating the second corrected predicted remaining discharge time by voltage RTV_2^{nd} by applying the coefficients (A, B, and C) of the second-order polynomial saved in the second lookup table 330 to equation 7.

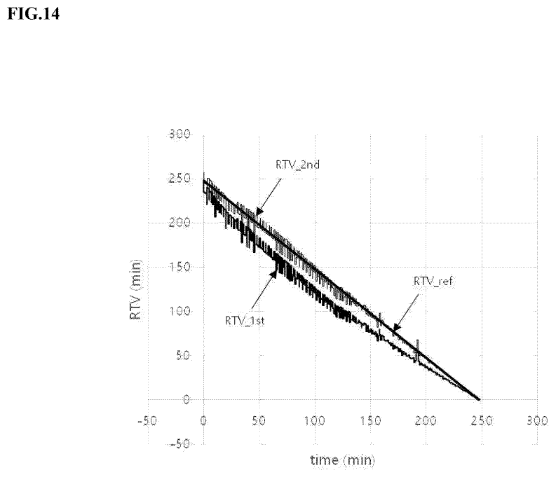

According to one or more embodiments of the present disclosure, FIG. 13 illustrates an exemplary simulation result of the first correction and second correction of RTV performed in the condition of −0.8 A at 25° C., and FIG. 14 illustrates an exemplary simulation result of the first correction and second correction of RTV performed in the condition of −0.8 A at 10° C.

With further reference to FIG. 13 and FIG. 14, it can be seen that the accuracy of the second correction result of RTV is improved compared to the first correction result of RTV in the condition of −0.8 A at 25° C. and of −0.8 A at 10° C.

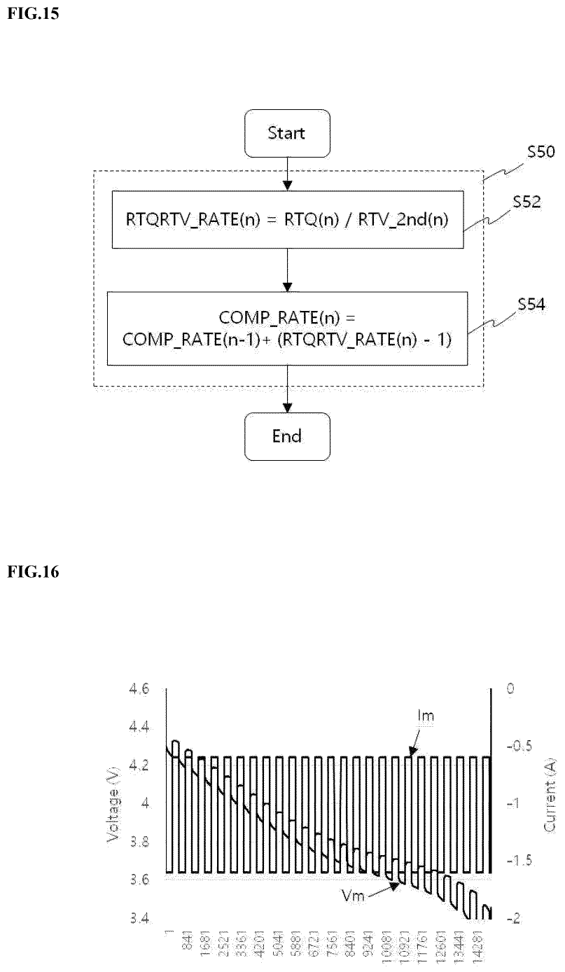

According to one or more embodiments of the present disclosure, FIG. 15 is an example flowchart for calculating the compensation coefficient of the charge variation amount COMP_RATE.

With further reference to FIG. 15, in step S52, a process of calculating the ratio of the predicted remaining discharge time by coulomb RTQ and the second corrected predicted remaining discharge time by voltage RTV, which can be expressed by the following equation.

$$RTQRTV\_RATE ( n ) = RTQ ( n ) / RTV\_ 2 nd ( n ) \qquad [ Equation 9 ]$$

In step S54, a process of calculating the compensation coefficient of the charge variation amount COMP_RATE, which can be expressed by the following equation.

$$COMP\_RATE ( n ) = COMP\_RATE ( n - 1 ) + ( RTQRTV\_RATE ( n ) - 1 ) \qquad [ Equation 10 ]$$

FIGS. 16-19 are drawings illustrating an effect according to one or more embodiments of the present disclosure, compared with the conventional art.

With further reference to FIGS. 16-19, one or more embodiments of the present disclosure adjusts the integrated ratio of the first coulomb counter with the compensation coefficient of the charge variation amount COMP_RATE calculated by the predicted remaining discharge time by coulomb RTQ and the predicted remaining discharge time by voltage RTV. That is, one or more embodiments of the present disclosure can present the simulation result in which the accuracy of estimating the state of charge SOC has been improved by applying a compensation coefficient of the charge variation amount COMP_RATE.

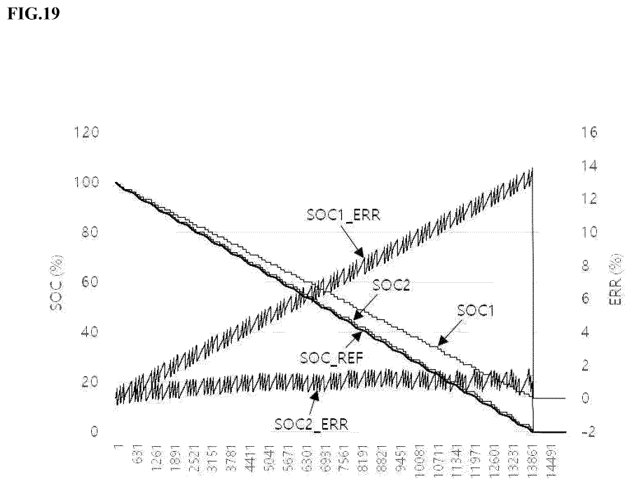

Qe1 of FIG. 18 is the computation result of the second estimated charge amount by the third coulomb counter when the compensation coefficient of the charge variation amount COMP_RATE is fixed to 1. Qe2 is, according to one or more embodiments of the present disclosure, the computation result of the second estimated charge amount Qe by the third coulomb counter when the compensation coefficient of the charge variation amount COMP_RATE calculated by the predicted remaining discharge time by voltage RTV and the predicted remaining discharge time by coulomb RTQ is applied.

Referring to FIG. 19, a large error in SOC1, which is the state of charge estimate when the compensation coefficient of the charge variation amount COMP_RATE is fixed to 1, occurs, however, it can be seen that SOC2, which is the state of charge estimate when the compensation coefficient of the charge variation amount COMP_RATE calculated based on the predicted remaining discharge time by voltage RTV and the predicted remaining discharge time by coulomb RTQ according to one or more embodiments of the present disclosure, estimates an accurate state of charge SOC.

The multiplier 350 can calculate the third charge variation amount Δ Q_cr by multiplying the compensation coefficient of the charge variation amount COMP_RATE which is the output of the second compensator 340 by the first charge variation amount Δ Q.

The multiplexer 360 can output a value between the fourth charge variation amount Δ Q_track which is the output of the first compensator 320 and the third charge variation amount Δ Q_cr generated by the second compensator 340 according to a mode. To this end, the multiplexer 360 receives a mode selection signal (mode) from a controller or the like that is not shown, and can output the selected value according to a mode selection signal (mode) between the third charge variation amount Δ Q_cr and the fourth charge variation amount Δ Q_track to the second charge variation amount Δ Q_comp. For example, as shown in equation 11, when the mode selection signal (mode) is ‘0’, the multiplexer 360 can output the third charge variation amount Δ Q_cr, and when the mode selection signal (mode) is ‘1’, the multiplexer 360 can output the fourth charge variation amount Δ Q_track. That is, the multiplexer 360 can allow the first compensator 320 and the second compensator 340 to operate selectively according to a mode selection signal (mode).

$$ΔQ\_comp = \{ \begin{matrix}ΔQ\_cr , & if mode = 0 \\ ΔQ\_track , & if mode = 1\end{matrix} \qquad [ Equation 11 ]$$

Meanwhile, FIG. 1 illustrates a case where the first compensator 320 and the second compensator 340 are used together, but the device for estimating a battery's state of charge 10 can selectively use either the first compensator 320 or the second compensator 340. In this case, the multiplexer 360 can be omitted or used to select the operation of the controller.

In addition, the first threshold value which is used to determine the operation of the first compensator 320 and the second threshold value which is used to determine the operation of the second compensator 340 can be the same value. In this case, the first compensator 320 can be operated when the magnitude of battery current Im is smaller than the first threshold value (or the second threshold value), the second compensator 340 can be operated when the magnitude of battery current Im is greater than the first threshold value (or the second threshold value). In addition, according to one or more embodiments, the second threshold value can have a value greater than the first threshold value. In this case, the first compensator 320 can be operated when the magnitude of battery current Im is smaller than the first threshold value, neither the first compensator 320 nor the second compensator 340 operates when the magnitude of battery current Im is greater than the first threshold value but smaller than that of the second threshold value, and the second compensator 340 can be operated when the magnitude of battery current Im is greater than the second threshold value.

According to one or more embodiments, the first compensator 320 can calculate the value of the fourth charge variation amount Δ Q_track differently depending on the magnitude of the battery voltage Vm and the estimated open circuit voltage OCVe. For example, when the battery voltage Vm is greater than the estimated open circuit voltage OCVe, the fourth charge variation amount Δ Q_track can be set to ‘0’ as shown in equation 12 so that the estimated open circuit voltage OCVe does not change. When the battery voltage Vm is smaller than the estimated open circuit voltage OCVe, the fourth charge variation amount Δ Q_track can be calculated as shown in equation 12, so that the estimated open circuit voltage OCVe follows the battery voltage Vm.

$$ΔQ\_track = \{ \begin{matrix}0 , & if Vm \geq OCVe \\ ( Vm - OCVe ) \cdot C 1 , & if Vm < OCVe\end{matrix} \qquad [ Equation 12 ]$$

The reason why the fourth charge variation amount Δ Q_track is set to ‘0’ in equation 12 when the battery voltage Vm is greater than the estimated open circuit voltage OCVe is to prevent the second estimated charge amount Qe and the charge state as a result from increasing while the battery maintains a discharge state when increasing the estimated open circuit voltage OCVe by assigning a positive value to the fourth charge variation amount Δ Q_track.

In addition, it is possible for the estimated open circuit voltage OCVe to gradually follow the battery voltage Vm by appropriately setting the first constant C1, where the first constant C1 is a constant that affects the speed at which the estimated open circuit voltage OCVe follows the battery voltage Vm in equation 12. According to one or more embodiments, the first constant C1 is set based on the internal resistance R of a battery to enable the estimated open circuit voltage OCVe to follow the battery voltage Vm at a speed that matches the time constant of a battery.

The third coulomb counter 400, CCE calculates the second estimated charge amount Qe by integrating the second charge variation amount Δ Q_comp. If the first coulomb counter 100 performs the integration function for each period, it is to be understood that the third coulomb counter 400 integrates the accumulated battery current Im without having any special period. Compared to a general method for integrating the current, the third coulomb counter 400 is different in that it does not directly integrate the battery current Im but integrates the second charge variation amount Δ Q_comp, which is a value compensated by the compensator 300.

The state of charge estimator 500 estimates a battery's state of charge based on the second estimated charge amount Qe. According to one or more embodiments, a battery's state of charge output by the state of charge estimator 500 can be, but is not limited to, SOC (state of charge). For example, a battery's state of charge may be a value corresponding to the second charge amount divided by the battery's design capacity.

According to one or more embodiments, the foregoing battery's state of charge estimator 10 is implemented in software and can perform its function with a computing device (such as CPU) while being stored in a computer-readable storage medium (such as memory). In this case, each element within the battery's state of charge estimator 10 is implemented as a separate module within software that implements the battery's state of charge estimator 10 to be distinguished from each other, but in some cases, each function may be implemented in a mixed state inside software without clear distinction. According to one or more embodiments, the battery's state of charge estimator 10 can be implemented in hardware such as Application Specific Integrated Circuit and Field Programmable Gate Array.

Terms such as “include,” “comprise,” or “have” herein mean that the corresponding components may be included, unless specifically stated to the contrary, and thus do not exclude other components. Rather, it should be interpreted as being able to include other components. All terms, including technical and scientific, unless otherwise defined, have the same meaning as generally understood by a person of ordinary skill in the technical field to which the present invention pertains. Commonly used terms, such as terms defined in a dictionary, should be interpreted as consistent with the meaning in the context of the related technology, and should not be interpreted in an idealized or overly formal sense unless explicitly defined in the present invention.

The above description is merely illustrative of the technical idea of the present disclosure, and those of ordinary skill in the technical field to which the present disclosure belongs will be able to make various modifications and variations without departing from the essential characteristics of the present disclosure. Accordingly, embodiments herein are not intended to limit the technical idea of the present disclosure, but to explain the technical idea, and the scope of the technical idea of the present disclosure is not limited by these embodiments. The scope of protection of this disclosure should be interpreted by the following claims, and all technical ideas within the scope equivalent thereto should be construed as being included in the scope of the present disclosure.

### DESCRIPTION OF REFERENCE SIGNS

10: a device for estimating a battery's state of charge
100: the first coulomb counter
200: the second coulomb counter
300: compensator
310: the first lookup table
320: the first compensator
330: the second lookup table
340: the second compensator
350: multiplier
360: multiplexer
400: the third coulomb counter
500: SOC estimator

What is claimed is:

1. A device for estimating a battery's state of charge, comprising:
a first coulomb counter that calculates a first charge variation amount Δ Q in each period by integrating battery current Im for each predetermined period;
a second coulomb counter that calculates a first estimated charge amount Qm by integrating the first charge variation amount Δ Q;
a compensator that calculates a second charge variation amount Δ Q_comp by compensating for the first charge variation amount Δ Q using the first estimated charge amount Qm and a second estimated charge amount Qe;
a third coulomb counter that calculates a second estimated charge amount Qe by integrating the second charge variation amount Δ Q_comp; and
an estimator that estimates a battery's state of charge based on the second estimated charge amount Qe.

2. The device for estimating a battery's state of charge of claim 1, wherein the compensator uses the second estimated charge amount Qe to calculate an estimated open circuit voltage OCVe, and uses the estimated open circuit voltage OCVe to calculate the second charge variation amount Δ Q_comp.

3. The device for estimating a battery's state of charge of claim 2, wherein the compensator uses a first lookup table LUT1 that contains data about a relationship between an amount of charge Q and an open circuit voltage OCV of a battery when calculating the estimated open circuit voltage OCVe by using the second estimated charge amount Qe.

4. The device for estimating a battery's state of charge of claim 2, wherein the compensator calculates the second charge variation amount Δ Q_comp by compensating for the first charge variation amount Δ Q so that a difference between the estimated open circuit voltage OCVe and a battery voltage Vm is reduced when a magnitude of the battery current Im is smaller than a first threshold value.

5. The device for estimating a battery's state of charge of claim 4, wherein the compensator calculates the second charge variation amount Δ Q_comp based on a value in which the estimated open circuit voltage OCVe is subtracted from the battery voltage Vm multiplied by a first constant C1.

6. The device for estimating a battery's state of charge of claim 5, wherein the first constant C1 is predetermined based on an internal resistance of the battery.

7. The device for estimating a battery's state of charge of claim 4, wherein the compensator calculates a compensation coefficient of the charge variation amount COMP_RATE based on a ratio of a predicted remaining discharge time by voltage RTV calculated according to the battery voltage Vm and a predicted remaining discharge time by coulomb RTQ calculated according to the second estimated charge amount Qe when a magnitude of the battery current Im is greater than a second threshold value, and calculates the second charge variation amount Δ Q_comp by multiplying the first charge variation amount Δ Q by the compensation coefficient of the charge variation amount COMP_RATE.

8. The device for estimating a battery's state of charge of claim 7, wherein the predicted remaining discharge time by coulomb RTQ is defined by a time it takes for a remaining capacity of a battery at the time to reach zero when discharging.

9. The device for estimating a battery's state of charge of claim 8, wherein the predicted remaining discharge time by coulomb RTQ is calculated based on the value in which the second estimated charge amount Qe is divided by an absolute value obtained by multiplying the battery current Im by the compensation coefficient of the charge variation amount COMP_RATE.

10. The device for estimating a battery's state of charge of claim 7, wherein the predicted remaining discharge time by voltage RTV is the time it takes for the current battery voltage Vm to reach a termination voltage Vterm when discharging.

11. The device for estimating a battery's state of charge of claim 10, wherein the predicted remaining discharge time by voltage RTV is calculated based on a value obtained by multiplying the value subtracting the battery voltage Vm from the termination voltage Vterm by an inverse of an open circuit voltage slope Δ T/Δ OCVm.

12. The device for estimating a battery's state of charge of claim 7, wherein the compensator creates the predicted remaining discharge time based on a first correction voltage RTV_1^{st} by linearizing discontinuous components of the predicted remaining discharge time by voltage RTV.

13. The device for estimating a battery's state of charge of claim 12, wherein the compensator creates the predicted remaining discharge time based on a second correction voltage RTV_2^{nd} by compensating for a characteristic difference according to a discharge current and battery temperature of the predicted remaining discharge time based on the first correction voltage RTV_1st.
